(19) United States
(12) Patent Application Publication
(10) Pub. No.: US 2023/0013188 A1
(43) Pub. Date: Jan. 19, 2023

(54) SYSTEM AND METHODS FOR SINGULATION OF GAN-ON-SILICON WAFERS

(71) Applicant: Navitas Semiconductor Limited, Dublin (IE)

(72) Inventors: George Chu, Irvine, CA (US); Nick Fichtenbaum, Torrance, CA (US); Kai-Ling Chiu, Hsinchu (TW); Daniel M. Kinzer, El Segundo, CA (US); Maher Hamdan, Lake Forest, CA (US); Pil Sung Park, Redondo Beach, CA (US)

(73) Assignee: Navitas Semiconductor Limited, Dublin (IE)

(21) Appl. No.: 17/812,385

(22) Filed: Jul. 13, 2022

Related U.S. Application Data
(60) Provisional application No. 63/203,279, filed on Jul. 15, 2021.
(60) Provisional application No. 63/262,437, filed on Oct. 12, 2021.

(51) Int. Cl. H01L 21/78; H01L 23/522

(52) U.S. Cl. CPC H01L 21/78; H01L 23/522; H01L 21/3065

(57) ABSTRACT

Structures and related techniques for singulating GaN-on-Si wafers are disclosed. In one aspect, a semiconductor wafer includes a silicon layer, and a gallium nitride (GaN) layer disposed on the silicon layer and defining a plurality of trenches that each extend to the silicon layer. In another aspect, the GaN layer includes one or more gallium nitride layers of different compositions. In yet another aspect, the wafer includes a plurality of dielectric layers disposed on the GaN layer. In yet another aspect, each of the plurality of trenches has a depth that is equal to a sum of a thickness of the GaN layer and a thickness of the plurality of the dielectric layers.

### CROSS-REFERENCE TO RELATED APPLICATION

This present application claims the benefit of U.S. Provisional application No. 63/203,279, filed on Jul. 15, 2021, entitled “Systems and Methods for Singulation of GaN-On-Silicon Wafers”, and U.S. Provisional application No. 63/262,437, filed on Oct. 12, 2021, entitled “Systems and Methods for Singulation of GaN-On-Silicon Wafers”, the entire contents of which are incorporated herein by reference for all purposes.

### FIELD

The described embodiments relate generally to singulation of gallium nitride (GaN) on silicon (Si) wafers, and more particularly, the present embodiments relate to systems and methods for singulating individual die from a silicon wafer that includes one or more GaN layers formed on the silicon wafer.

### BACKGROUND

In semiconductor technology, gallium nitride (GaN) is one compound semiconductor material that is used to form various devices, such as high power and/or high voltage transistors. These devices can be formed by growing epitaxial layers on silicon, silicon carbide, sapphire, gallium nitride, or other substrates. Often, such devices are formed using a heteroepitaxial junction of aluminum gallium nitride (AlGaN) and GaN. This structure is known to form a high electron mobility two-dimensional electron gas (2DEG) at the interface of the two materials. The electron gas can have a charge density in the 2DEG. It is desirable to have efficient manufacturing methods for GaN-on-Si wafers.

### SUMMARY

In some embodiments, a semiconductor wafer is disclosed. The semiconductor wafer includes a silicon layer, and a gallium nitride (GaN) layer disposed on the silicon layer and defining a plurality of trenches that each extend to the silicon layer.

In some embodiments, the GaN layer includes one or more gallium nitride layers of different compositions.

In some embodiments, the semiconductor wafer further includes a plurality of dielectric layers disposed on the GaN layer.

In some embodiments, each of the plurality of trenches has a depth that is equal to a sum of a thickness of the GaN layer and a thickness of the plurality of the dielectric layers.

In some embodiments, the plurality of trenches is formed at front-end-of-line (FEOL).

In some embodiments, the plurality of trenches is formed at middle-of-line (MOL).

In some embodiments, the plurality of trenches is formed at back-end-of-line (BEOL).

In some embodiments, a method of forming a semiconductor die is disclosed. The method includes forming a silicon layer, forming a gallium nitride (GaN) layer on the silicon layer, defining a plurality of trenches within the GaN layer that each extend to the silicon layer, and singulating the semiconductor die along the plurality of trenches.

In some embodiments, in the disclosed method the GaN layer includes one or more gallium nitride layers of different compositions.

In some embodiments, in the disclosed method the silicon layer defines an outer periphery of the semiconductor die and the GaN layer is recessed from the outer periphery.

In some embodiments, the disclosed method further includes forming a plurality of dielectric layers on the GaN layer.

In some embodiments, defining the plurality of trenches is performed at front-end-of-line (FEOL).

In some embodiments, defining the plurality of trenches is performed at middle-of-line (MOL).

In some embodiments, defining the plurality of trenches is performed at back-end-of-line (BEOL).

In some embodiments, a semiconductor die is disclosed. The semiconductor die includes a silicon layer defining an outer periphery of the semiconductor die, a gallium nitride (GaN) layer disposed on the silicon layer and recessed from the outer periphery.

In some embodiments, the GaN layer includes one or more gallium nitride layers of different compositions.

In some embodiments, the semiconductor die further includes a plurality of dielectric layers disposed on the GaN layer.

In some embodiments, the recess in the GaN layer is formed at front-end-of-line (FEOL).

In some embodiments, the recess in the GaN layer is formed at middle-of-line (MOL).

In some embodiments, the recess in the GaN layer is formed at back-end-of-line (BEOL).

### BRIEF DESCRIPTION OF THE DRAWINGS

FIG. 1 illustrates a GaN-on-Si wafer with GaN-free dicing lanes according to an embodiment of the disclosure;

FIG. 2A illustrates a diagram showing a side view of the GaN-on-Si wafer of FIG. 1 according to an embodiment of the disclosure. FIG. 2B illustrates a dicing lane cut that can be formed by a sawing operation according to an embodiment of the disclosure;

FIGS. 3A to 3E illustrate methods for forming GaN-free dicing lanes at front-end-of-the-line (FEOL) according to an embodiment of the disclosure;

FIGS. 4A to 4C illustrate methods for forming GaN-free trench at FEOL by a combination of dry and wet etching according to an embodiment of the disclosure;

FIG. 5 illustrates a flowchart of a process for forming GaN-free dicing lanes on a GaN-on-Si wafer at FEOL according to an embodiment of the disclosure;

FIGS. 6A to 6E illustrate methods for forming GaN-free dicing lanes at middle-of line (MOL) according to an embodiment of the disclosure;

FIGS. 7A to 7C illustrate methods for forming GaN-free trench at MOL by a combination of dry and wet etching according to an embodiment of the disclosure;

FIG. 8 illustrates a flowchart of a process for forming GaN-free dicing lanes on a GaN-on-Si wafer at MOL according to an embodiment of the disclosure;

FIGS. 9A to 9D illustrate methods for forming GaN-free dicing lanes at back-end-of-line (BEOL) according to an embodiment of the disclosure;

FIGS. 10A to 10C illustrate methods for forming GaN-free trench at BEOL by a combination of dry and wet etching according to an embodiment of the disclosure; and

FIG. 11 illustrates a flowchart of a process for forming GaN-free dicing lanes on a GaN-on-Si wafer at BEOL according to an embodiment of the disclosure.

### DETAILED DESCRIPTION

Devices, structures and related techniques disclosed herein relate generally to singulation of gallium nitride (GaN) on silicon (Si) wafers. More specifically, devices, structures, and related techniques disclosed herein relate to systems and methods for singulating (e.g., dicing) individual die from a silicon wafer that includes one or more GaN layers formed on the silicon wafer (e.g., forming a GaN-on-Si wafer). In various embodiments, systems and methods for singulating individual die from a GaN-on-Si wafer can enable efficient singulation of the wafers while preventing chipping, delamination and/or fracturing of the GaN layer resulting in improved reliability of the die. This can enable faster sawing velocity, providing efficient and economical dicing of the GaN-on-Si wafer.

In some embodiments, a GaN-free dicing lane can be fabricated by forming a deep etch in the GaN-on-Si wafer along each dicing lane in the shape of a trench. This trench can be formed at any stage in the manufacturing process and can be formed through all of the layers except the silicon substrate. At the end of the manufacturing process, a sawing operation can be performed along the GaN-free dicing lane where the saw cuts through and is only in contact with the silicon substrate. Because the saw is only in contact with the silicon substrate there is no chipping, delamination and/or fracturing of the GaN layer. In various embodiments, the GaN-free dicing lane can eliminate a need for laser grooving in the dicing process, thus reducing manufacturing costs while preventing die cracking. In some embodiments, the GaN-free dicing lane can reduce die area by reducing the size of non-active die area along each dicing lane used to prevent die cracking. In this way, the GaN-free dicing lane can increase the number of dice that can be harvested from a wafer for the same active die area, thus enabling a reduction in die costs. Various inventive embodiments are described herein, including methods, processes, systems, devices, and the like.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

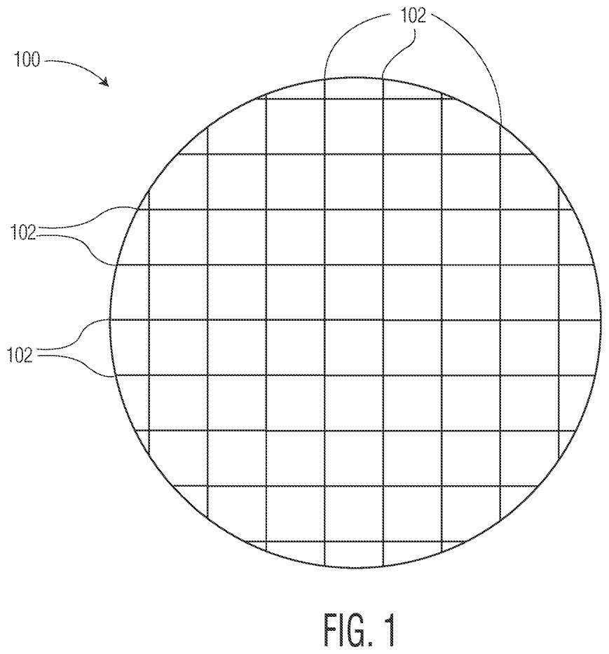

FIG. 1 illustrates a plan view of a GaN-on-Si wafer 100 with GaN-free dicing lanes 102 according to an embodiment of the disclosure. As shown in FIG. 1, the GaN-free dicing lanes 102 can be used to singulate individual die from the GaN-on-Si wafer 100. The GaN-on-Si wafer 100 can include a silicon substrate and one or more GaN layers formed on the silicon substrate, as described in more detail below.

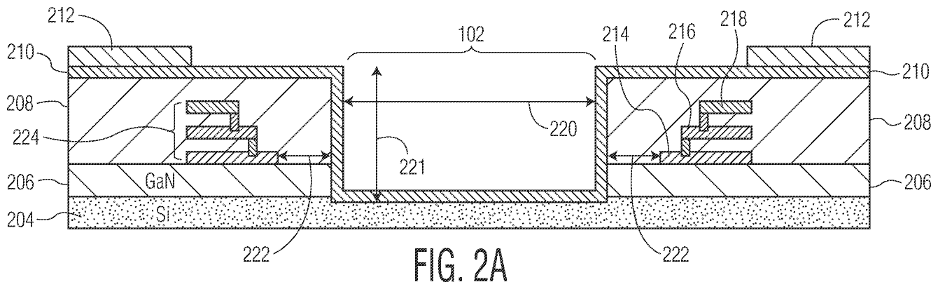

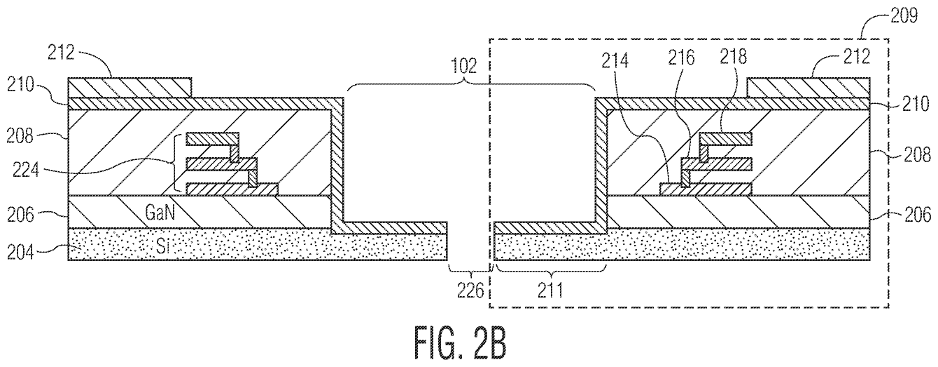

FIG. 2A illustrates a simplified partial cross-sectional view of the GaN-on-Si wafer 100 shown in FIG. 1 in the region of a GaN-free dicing lane 102, according to an embodiment of the disclosure. As shown in FIG. 2A, a GaN-free dicing lane 102 can be formed where a GaN layer 206 has been removed from the GaN-free dicing lane 102, leaving only silicon layer 204 in the dicing lane 102. In some embodiments, the GaN-free dicing lane may be referred to as a trench. In various embodiments, the GaN layer 206 may include multiple gallium nitride layers having different compositions. FIG. 2A also shows the GaN-on-Si wafer having routing and ohmic contact layers 224, one or more dielectric layers 208, a passivation layer 210 and a polyimide layer 212. Routing and ohmic contact layers 224 can include metal layers such as a first metal layer 214, which can be used for ohmic contact formation in an active device, a second metal layer 216 and a third metal layer 218. In some embodiments, the GaN-free dicing lane 102 may have a depth 221 that is equal to a sum of thicknesses of GaN layer 206, dielectric layer 208 and passivation layer 210. Removal of the GaN layer 206 in the dicing lane 102 can enable efficient singulation of the GaN-on-Si wafer 100 while preventing chipping, delamination and/or fracturing of the GaN layer resulting in improved reliability of the die. This can enable faster sawing velocity, providing efficient and economical dicing of the GaN-on-Si wafer 100. In various embodiments, the GaN-free dicing lane 102 can be fabricated by etching a trench in the GaN-on-Si wafer 100 along each dicing lane 102, to remove a portion of the GaN layer 206. This trench can be formed at any stage in manufacturing process as described in detail further below. In some embodiments, the trench can be formed through all of the layers of the GaN-on-Si wafer 100 except the silicon layer 204.

FIG. 2B illustrates the simplified partial cross-sectional view of the GaN-on-Si wafer 100 shown in FIG. 2A after a sawing operation forms a dicing lane cut 226 to singulate the wafer. Individual die 209 can be formed in this way. The individual die 209 includes a silicon layer 204 that defines a periphery 211, where the GaN layer 206 has been recessed. The sawing operation can be performed by a wafer dicing saw, laser or other suitable singulation process. In some embodiments, at the end of the manufacturing process, a sawing operation can be performed along the GaN-free dicing lane 102 where the saw cuts through and is only in contact with the silicon substrate 204. Because the saw is only in contact with the silicon substrate 204 there is no chipping, delamination and/or fracturing of the GaN layer 206. More specifically, in some embodiments a width of GaN-free dicing lane 102 can be wider than a width of the dicing saw that forms the dicing lane cut 226.

In various embodiments, the GaN-free dicing lane 102 can eliminate a need for laser grooving in the dicing process, thus reducing assembly costs while preventing die cracking. In some embodiments, the GaN-free dicing lane 102 can reduce die area by reducing the size of non-active die area along each dicing lane used to prevent die cracking. In this way, the GaN-free dicing lane can increase the number of die that can be harvested from a wafer for the same active die area, thus enabling a reduction in die costs. As an example, the number of good die per wafer for a 1 mm² die can increase by between 10 to 20 percent using the structures and methods disclosed herein. In various embodiments, a ratio of a size of non-active die area along the dicing lanes 222 to a size of the GaN-free dicing lane 220 can be used in order to maximize the number of dice harvested from a wafer. This ratio can be part of a process design kit (PDK) used in design of integrated circuits on GaN-on-Si wafers. By reducing a size of the non-active area along the dicing lanes, die to die spacing can be reduced, for example, from 160 um to 80 um, or to other suitable dimensions. Furthermore, the width of the GaN-free dicing lane can be adjustable.

In some embodiments, the GaN-free dicing lane can be formed by dry etching processes and/or by a combination of dry and wet etching processes. In various embodiments, the GaN-free dicing lane can be formed at the front-end-of-the-line (FEOL), at the middle-of-line (MOL), or at the back-end-of-the-line (BEOL) of the wafer fabrication process. In some embodiments, a width of the GaN-free region defined within the dicing lane can be 60 um. It will be understood by those skilled in the art that the width of the GaN-free region can be a function of wafer thickness and wafer saw width.

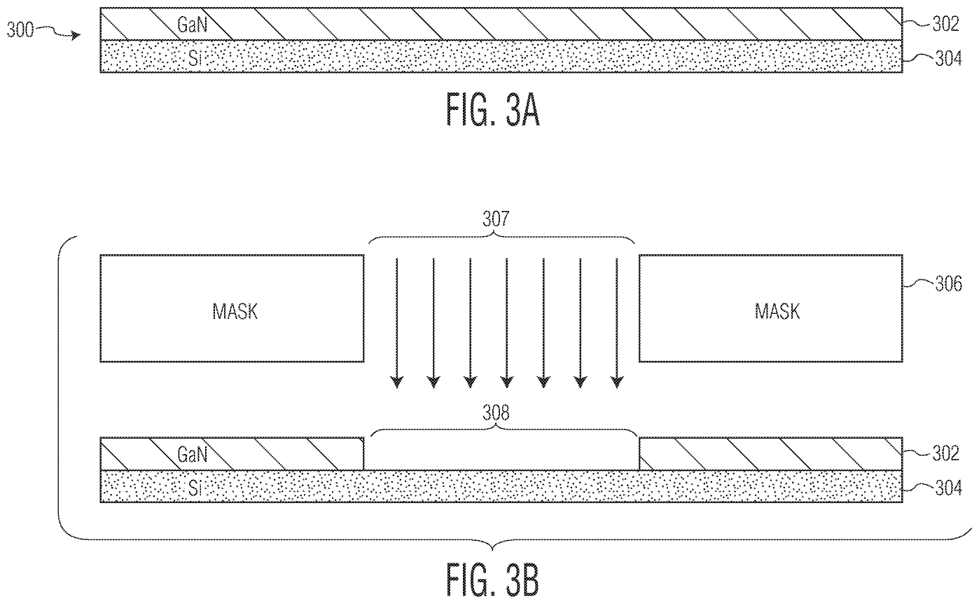

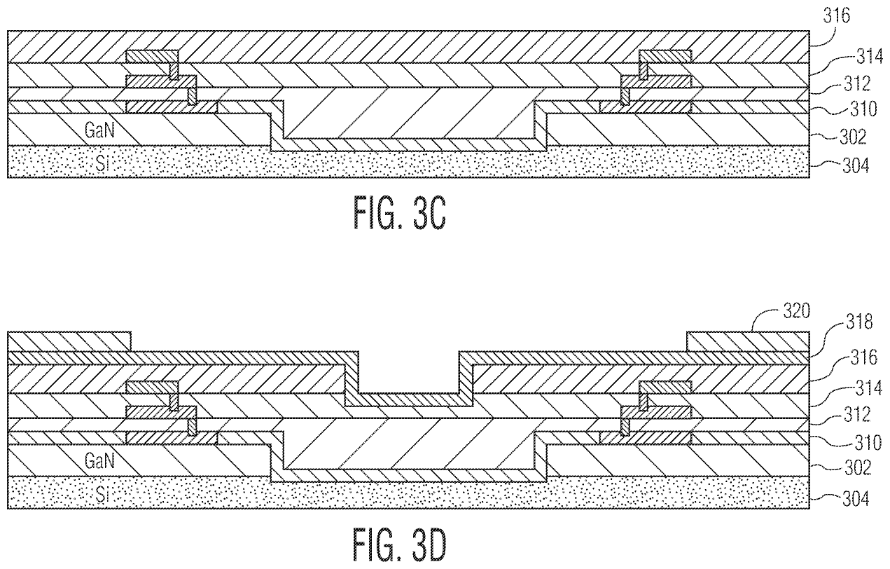

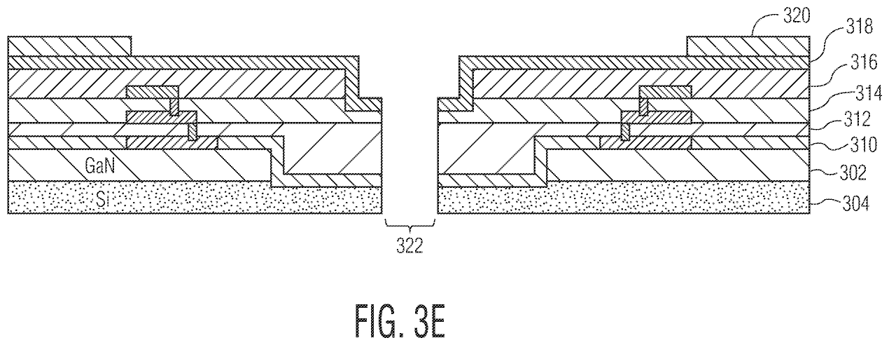

Now referring to FIGS. 3A to 3E, systems and methods for forming GaN-free dicing lanes at front-end-of-the-line (FEOL) are illustrated, according to an embodiment of the disclosure. In FIG. 3A, a GaN-on-Si wafer 300 is provided and includes a GaN layer 302 formed on a Si layer 304. A portion of the GaN layer 302 can be etched away to form a GaN-free trench 308 as shown in FIG. 3B. A mask 306 can be used to protect the active regions of the wafer during the etching process. In some embodiments, dry etching 307 can be used to form the GaN-free trench 308. In various embodiments, wet etching or a combination of dry and wet etching may be used to form the GaN-free trench as described in detail further below. As shown in FIG. 3C, after the GaN-free trench 308 has been formed the GaN-on-Si wafer 300 can be processed through fabrication steps to add active and passive regions including, but not limited to, metal layers, a first, second and third inter-layer dielectrics 310, 312 and 314, respectively, and a capping dielectric layer 316. As appreciated by one of ordinary skill in the art having the benefit of this disclosure, the GaN-on-Si wafer may be processed to have as many layers as is suitable for various applications.

The GaN-on-Si wafer 300 can then be passivated by forming a silicon nitride (SiN) layer 318 on the wafer, followed by forming a polyimide layer 320 as shown in FIG. 3D. The GaN-on-Si wafer can then be singulated by a sawing operation that cuts through the GaN-free dicing lane to form a cut 322 as shown in FIG. 3E. Because the dicing lane does not include a GaN layer and is wider than a width of the saw, the saw does not come into contact with the GaN layer 302, thus preventing chipping and/or fracturing of the GaN layer 302. This can improve the reliability of the GaN-on-Si die harvested from the wafer. Moreover, by eliminating the GaN layer in the dicing lane, a laser grooving step can be eliminated resulting in improved manufacturing efficiencies and saving costs.

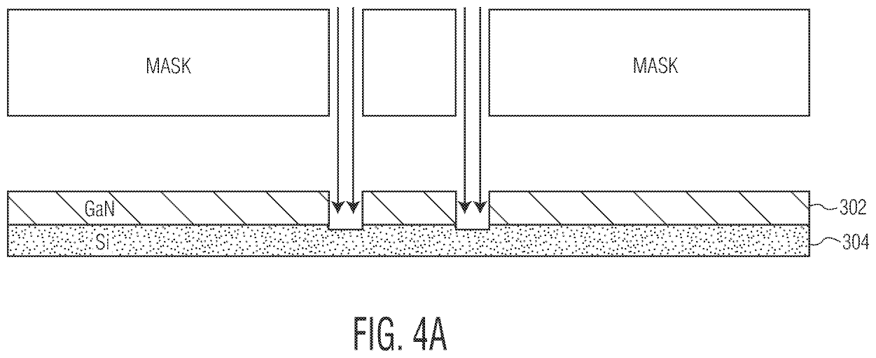

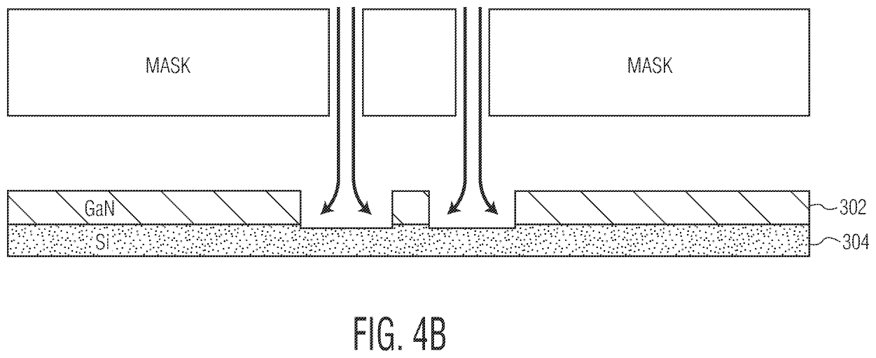

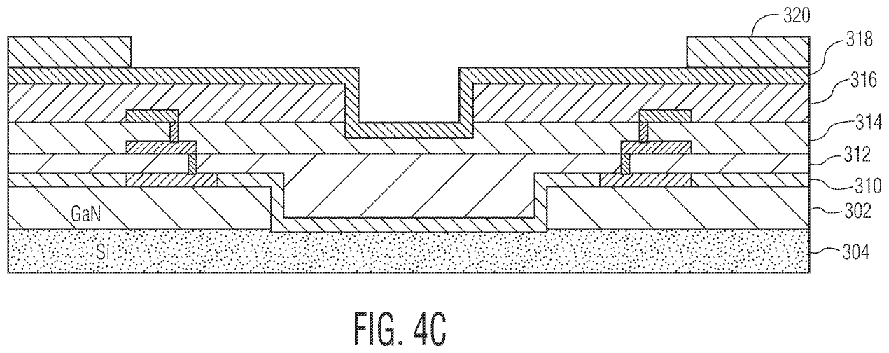

FIGS. 4A and 4B illustrate methods for forming the GaN-free trench 308 at FEOL by a combination of dry and wet etching, according to an embodiment of the disclosure. As shown in FIG. 4A, dry etching can be used to remove regions of the GaN layer and form pairs of relatively narrow GaN-free trenches. This can be followed by a wet etching process where the pair of GaN-free trenches can be enlarged by the wet etching process, as shown in FIG. 4B. After the wet etching process, a single GaN-free trench remains. Next, the GaN-on-Si wafer can be processed through fabrication steps as shown in FIG. 4C, followed by processes as described in FIGS. 3D and 3E to singulate the GaN-on-Si wafer.

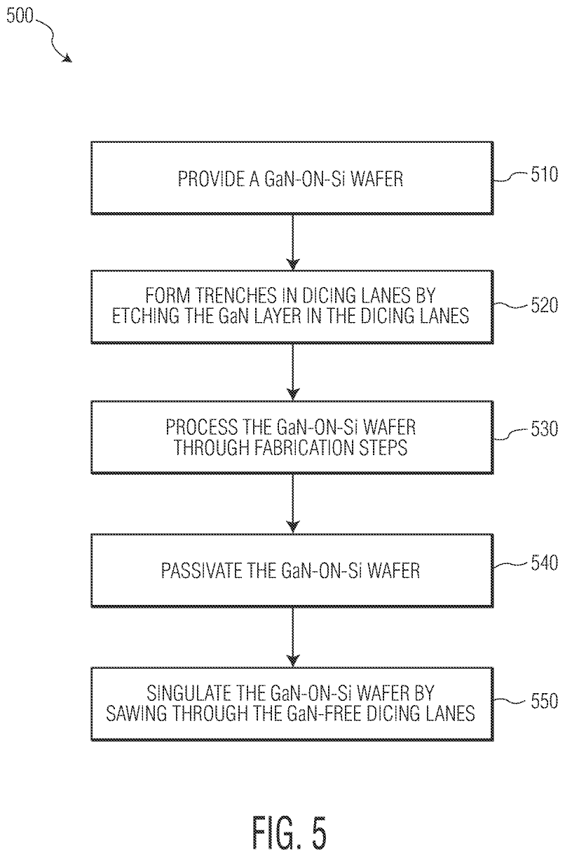

FIG. 5 illustrates a flowchart of an example process 500 for forming GaN-free dicing lanes on a GaN-on-Si wafer at FEOL according to an embodiment of the disclosure. At block 510, a GaN-on-Si wafer is provided. At block 520, the GaN layer in the GaN-free dicing lanes can be etched away. At block 530, the GaN-on-Si wafer can be processed though the fabrication steps. At block 540, the GaN-on-Si wafer can be passivated by forming a SiN layer on the GaN-on-Si wafer. At block 550, the GaN-on-Si wafer can be singulated by sawing through the GaN-free dicing lanes. Process 500 can provide for an efficient singulation of GaN-on-Si wafer and provide increased number of harvested good die per wafer because the saw does not come into contact with the GaN layer, preventing chipping and/or fracturing of the GaN layer. Further, process 500 can provide increased number of harvested good die per wafer because non-active area along dicing lanes can be reduced in size, thus saving die area and costs. It will be appreciated that process 500 is illustrative and that variations and modifications are possible. Steps described as sequential may be executed in parallel, order of steps may be varied, and steps may be modified, combined, added or omitted.

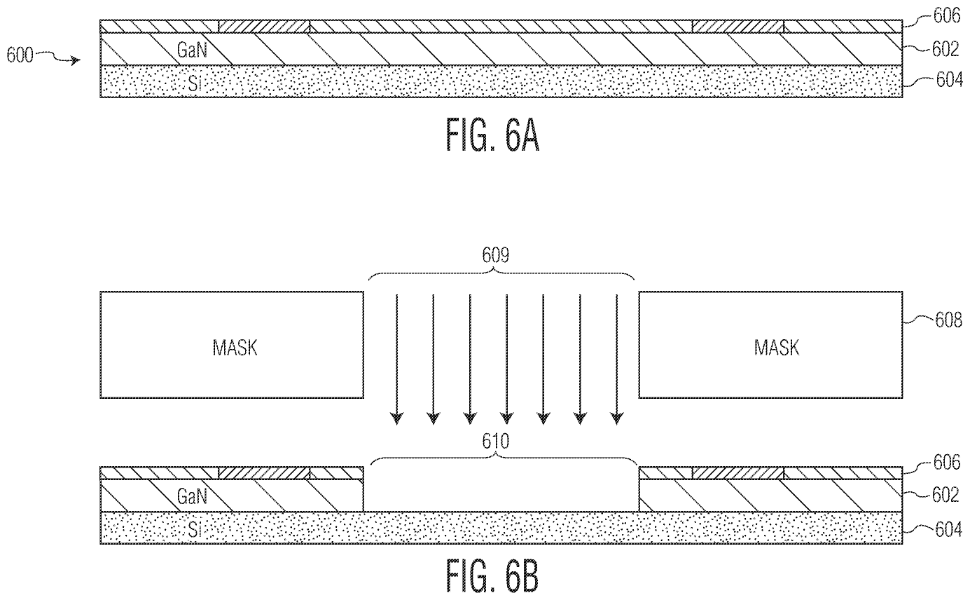

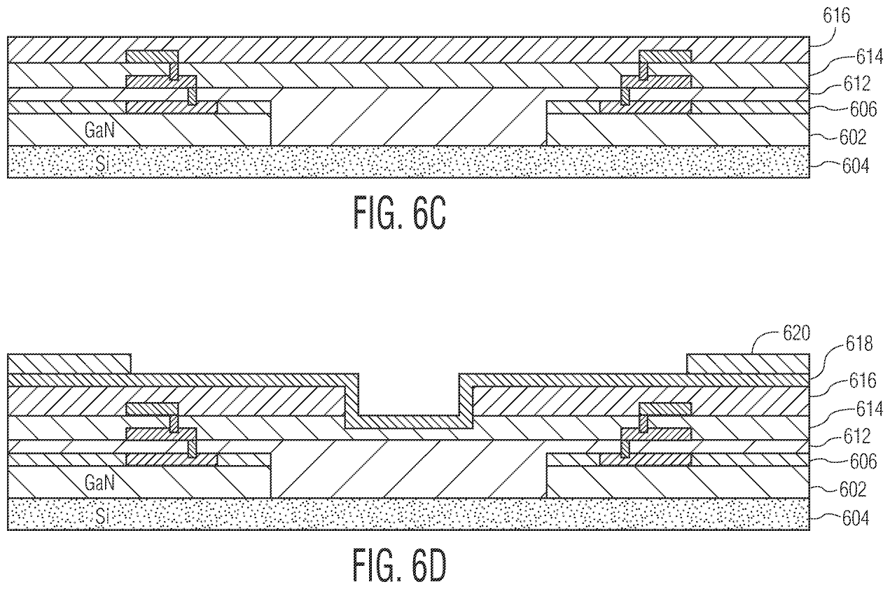

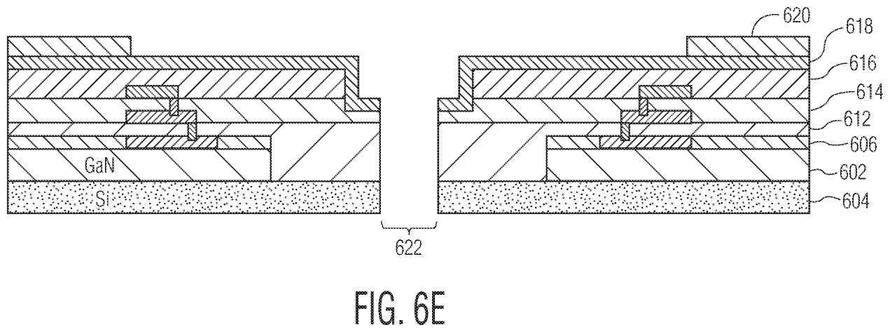

Now referring to FIGS. 6A to 6E, systems and methods for forming GaN-free dicing lanes at middle-of-line (MOL) are illustrated, according to an embodiment of the disclosure. As shown in FIG. 6A, a GaN-on-Si wafer 600 can be provided which has been processed through FEOL. The GaN-on-Si wafer 600 can include a Si layer 604, a GaN layer 602 formed on the Si layer 604, and a first metal layer and a first inter-layer dielectric layer 606 formed on the GaN layer 602. The GaN layer 602 and the layers above it can be etched away to form a GaN-free trench 610 as shown in FIG. 6B. A mask 608 can be used to protect the active regions of the wafer during the etching process. In some embodiments, dry etching 609 can be used to form the GaN-free trench 610. In various embodiments, wet etching or a combination of dry and wet etching may be used to form the GaN-free trench 610 as described in more detail further below. As shown in FIG. 6C, after the GaN-free trench 610 has been formed the GaN-on-Si wafer 600A can be processed through fabrication steps to add active and passive regions including, but not limited to, metal layers, a second and third inter-layer dielectrics 612 and 614, respectively, and a capping dielectric layer 616. As appreciated by one of ordinary skill in the art having the benefit of this disclosure, the GaN-on-Si wafer may be processed to have as many layers as is suitable for various applications.

The GaN-on-Si wafer 600 can then be passivated by forming a silicon nitride (SiN) layer 618 on the wafer followed by forming a polyimide layer 620 as shown in FIG. 6D. The GaN-on-Si wafer can then be singulated by a sawing operation that cuts through the GaN-free dicing lane to form a cut 622 as shown in FIG. 6E. Because the dicing lane does not include a GaN layer and because the GaN-free trench 610 is wider than a width of the saw, the saw does not come into contact with the GaN layer 602, thus preventing chipping and/or fracturing of the GaN layer 602. This can improve the reliability of the GaN-on-Si die harvested from the wafer. Moreover, by eliminating the GaN layer in the dicing lane, a laser grooving step can be eliminated resulting in improved manufacturing efficiencies and saving costs.

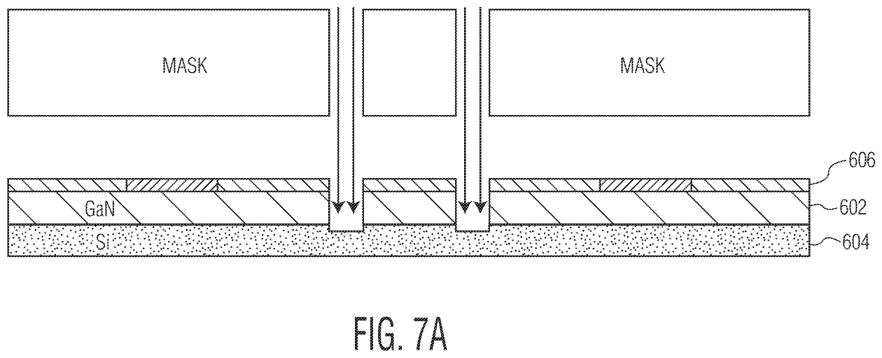

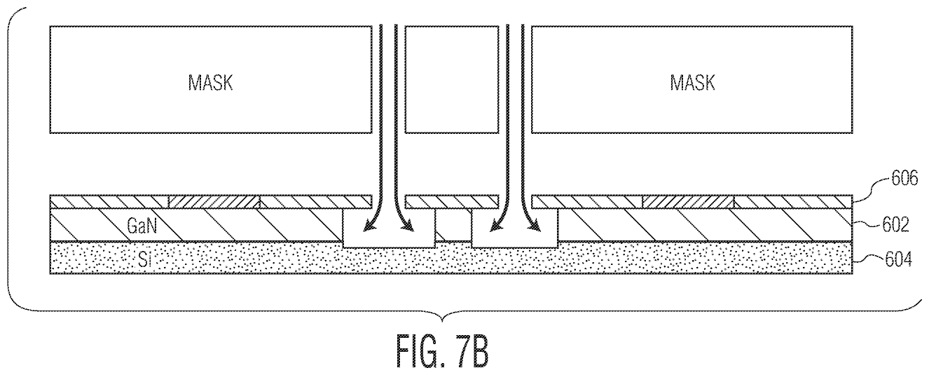

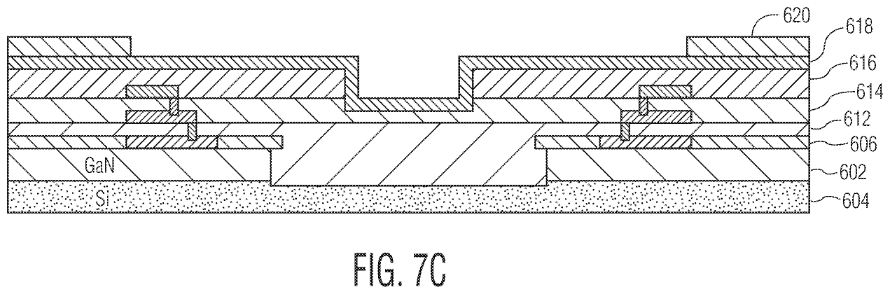

FIGS. 7A and 7B illustrate methods for forming the GaN-free trench 610 at MOL by a combination of dry and wet etching according to an embodiment of the disclosure. As shown in FIG. 7A, dry etching can be used to remove regions of the GaN layer and form pairs of relatively small GaN-free trenches. This can be followed by a wet etching process where the pair of GaN-free trenches can be enlarged by the wet etching as shown in FIG. 7B so a unitary GaN free trench remains. After the GaN-free trench has been formed, the GaN-on-Si wafer can be processed through fabrication steps as shown in FIG. 7C, followed by processes as described in FIGS. 6D and 6E to singulate the GaN-on-Si wafer.

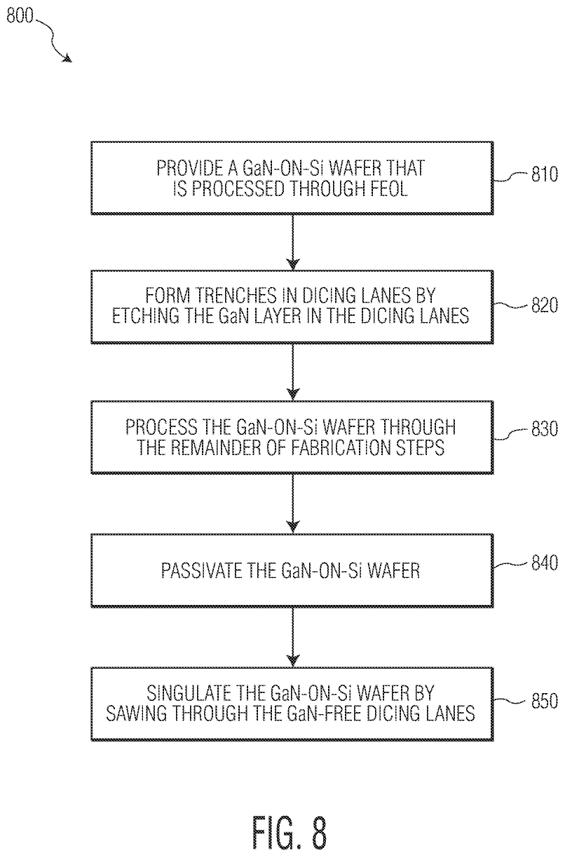

FIG. 8 illustrates a flowchart of an example process 800 for forming GaN-free dicing lanes on a GaN-on-Si wafer at MOL according to an embodiment of the disclosure. At block 810, a GaN-on-Si wafer is provided that has been processed through FEOL. At block 820, the GaN layer in the GaN-free dicing lanes can be etched away. At block 830, the GaN-on-Si wafer can be processed through the remainder of fabrication steps. At block 840, the GaN-on-Si wafer can be passivated by forming a SiN layer on the GaN-on-Si wafer. At block 850, the GaN-on-Si wafer can be singulated by sawing through the GaN-free dicing lanes. Process 800 can provide for an efficient singulation of GaN-on-Si wafer and provide increased number of harvested good die per wafer because the saw does not come into contact with the GaN layer, preventing chipping and/or fracturing of the GaN layer. Further, process 800 can provide increased number of harvested good die per wafer because non-active area along dicing lanes can be reduced in size, thus saving die area and costs. It will be appreciated that process 800 is illustrative and that variations and modifications are possible. Steps described as sequential may be executed in parallel, order of steps may be varied, and steps may be modified, combined, added or omitted.

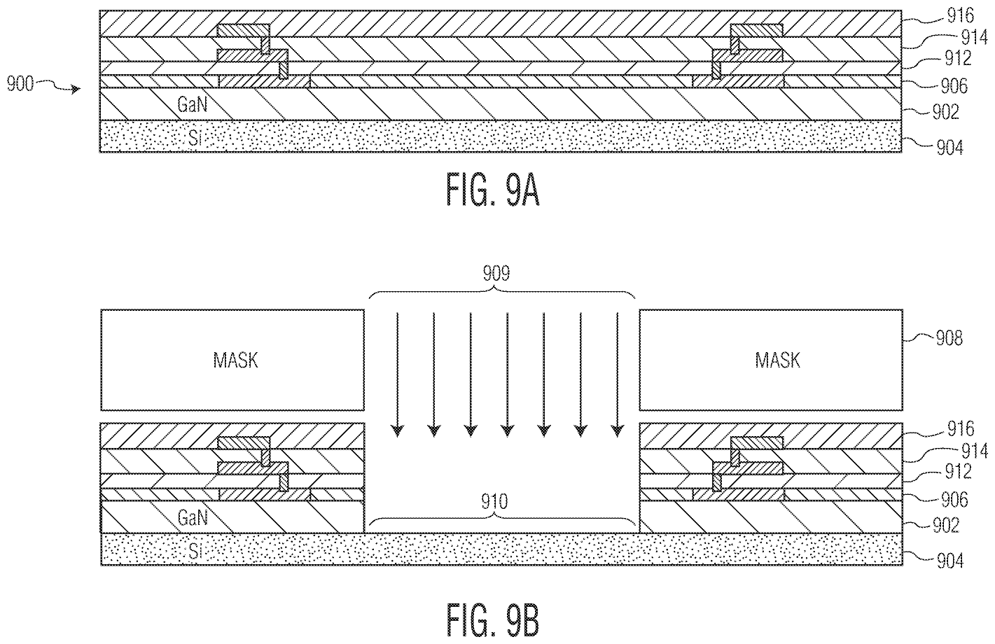

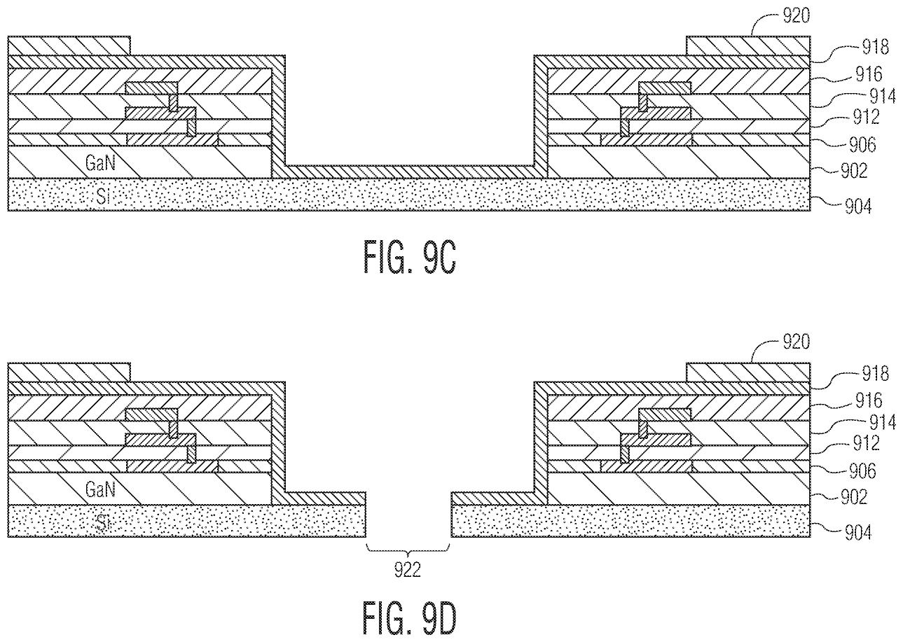

Now referring to FIGS. 9A to 9D, systems and methods for forming GaN-free dicing lanes after back-end-of-line (BEOL) processing are illustrated, according to an embodiment of the disclosure. As shown in FIG. 9A, a GaN-on-Si wafer 900 can be provided which has been processed through BEOL. The GaN-on-Si wafer 900 can include a Si layer 904, a GaN layer 902 formed on the Si layer 904, metal layers and a first, second, and third inter-layer dielectric layers 906, 912 and 914, respectively, and a capping dielectric layer 916. The GaN layer 902 and the layers above it can be etched away to form a GaN-free trench 910 as shown in FIG. 9B. A mask 908 can be used to protect the active regions of the wafer during the etching process. In some embodiments, dry etching 909 can be used to form the GaN-free trench 910. In various embodiments, wet etching or a combination of dry and wet etching may be used to form the GaN-free trench 910. As appreciated by one of ordinary skill in the art having the benefit of this disclosure, the GaN-on-Si wafer may include as many layers as is suitable for various applications.

As shown in FIG. 9C, after the GaN-free trench 910 has been formed the GaN-on-Si wafer 900 can be passivated by forming a silicon nitride (SiN) layer 918 on the wafer followed by forming a polyimide layer 920. The GaN-on-Si wafer 900 can then be singulated by a sawing operation that cuts through the GaN-free dicing lane to form a cut 922 as shown in FIG. 9D. Because the dicing lane does not include a GaN layer, which can be chipped and/or fractured by the sawing operation, the saw does not come into contact with the GaN layer 902, thus preventing chipping and/or fracturing of the GaN layer 902. This can improve the reliability of the GaN-on-Si die harvested from the wafer. Moreover, by eliminating the GaN layer in the dicing lane, a laser grooving step can be eliminated resulting in improved manufacturing efficiencies and saving costs.

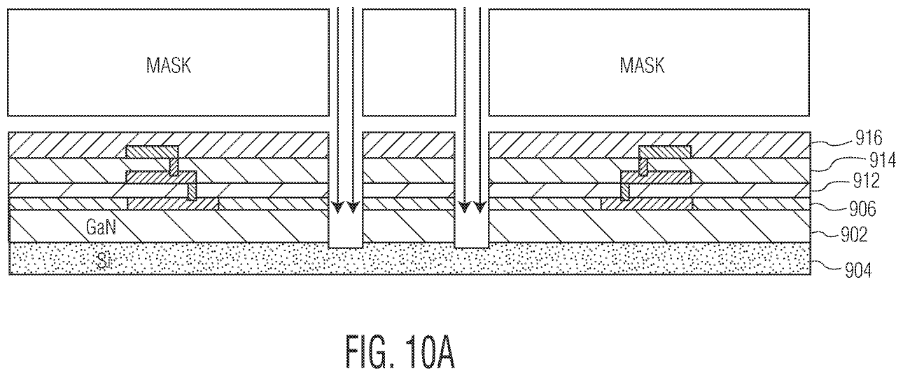

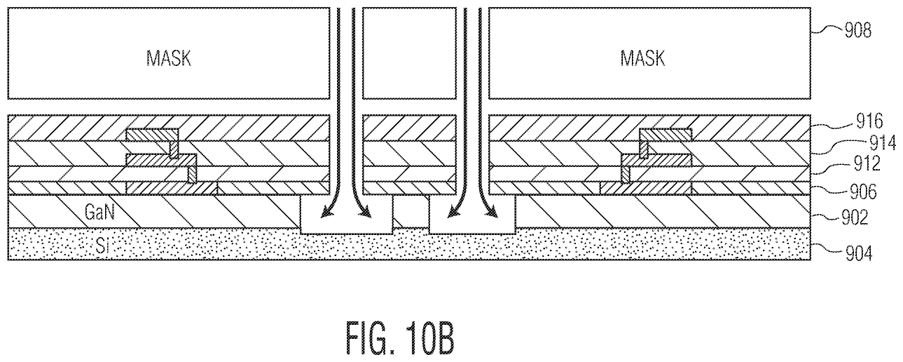

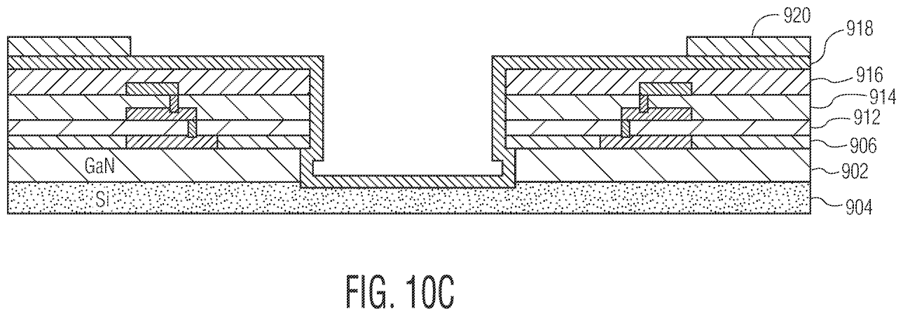

FIGS. 10A and 10B illustrate methods for forming the GaN-free trench 910 at BEOL by a combination of dry and wet etching according to an embodiment of the disclosure. As shown in FIG. 10A, dry etching can be used to remove regions of the GaN layer and form pairs of relatively small GaN-free trenches. This can be followed by wet etching process where the pair of GaN-free trenches can be enlarged to form a unitary GaN-free trench by the wet etching as shown in FIG. 10B. The GaN-on-Si wafer can then be passivated by a SiN layer and a polyimide layer can be formed on the wafer as shown in FIG. 10C. The GaN-on-Si wafer can then be singulated as described in in FIG. 9D.

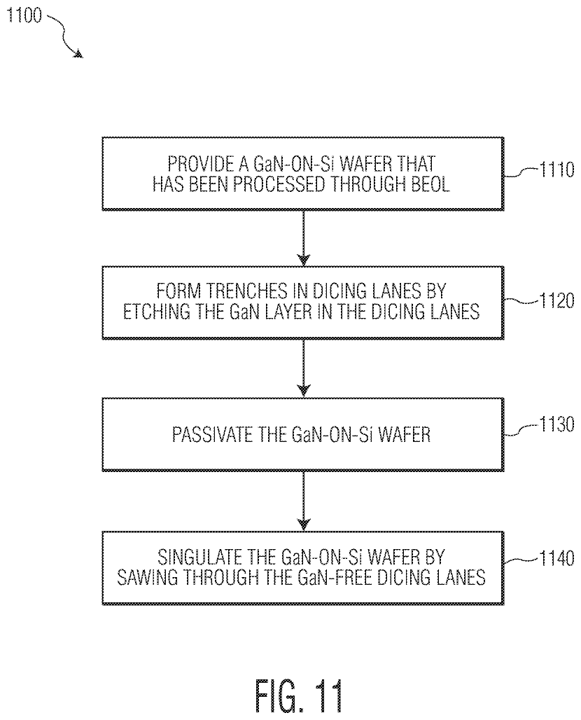

FIG. 11 illustrates a flowchart of an example process 1100 for forming GaN-free dicing lanes on a GaN-on-Si wafer at MOL according to an embodiment of the disclosure. At block 1110, a GaN-on-Si wafer is provided that has been processed through BEOL. At block 1120, the GaN layer in the GaN-free dicing lanes can be etched away. At block 1130, the GaN-on-Si wafer can be passivated by forming a SiN layer on the GaN-on-Si wafer. At block 1140, the GaN-on-Si wafer can be singulated by sawing through the GaN-free dicing lanes. Process 1100 can provide for an efficient singulation of GaN-on-Si wafer and provide increased number of good die per wafer harvested because the saw does not come into contact with the GaN layer, preventing chipping and/or fracturing of the GaN layer. Further, process 1100 can provide increased number of harvested good die per wafer because non-active area along dicing lanes can be reduced in size, thus saving die area and costs. It will be appreciated that process 1100 is illustrative and that variations and modifications are possible. Steps described as sequential may be executed in parallel, order of steps may be varied, and steps may be modified, combined, added or omitted.

In some embodiments, combination of the structures and techniques disclosed herein can be utilized in order to form GaN-free dicing lanes. Although structures and methods are described and illustrated herein with respect to GaN-on-Si wafers, embodiments of the disclosure are suitable for use with other compound semiconductor wafers.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A semiconductor wafer comprising:
a silicon layer; and
a gallium nitride (GaN) layer disposed on the silicon layer and defining a plurality of trenches that each extend to the silicon layer.

2. The semiconductor wafer of claim 1, wherein the GaN layer comprises one or more gallium nitride layers of different compositions.

3. The semiconductor wafer of claim 1, further comprising a plurality of dielectric layers disposed on the GaN layer.

4. The semiconductor wafer of claim 3, wherein each of the plurality of trenches has a depth that is equal to a sum of a thickness of the GaN layer and a thickness of the plurality of the dielectric layers.

5. The semiconductor wafer of claim 1, wherein the plurality of trenches is formed at front-end-of-line (FEOL).

6. The semiconductor wafer of claim 1, wherein the plurality of trenches is formed at middle-of-line (MOL).

7. The semiconductor wafer of claim 1, wherein the plurality of trenches is formed at back-end-of-line (BEOL).

8. A method of forming a semiconductor die, the method comprising:
forming a silicon layer;
forming a gallium nitride (GaN) layer on the silicon layer;
defining a plurality of trenches within the GaN layer that each extend to the silicon layer; and
singulating the semiconductor die along the plurality of trenches.

9. The method of claim 8, wherein the GaN layer comprises one or more gallium nitride layers of different compositions.

10. The method of claim 8, wherein the silicon layer defines an outer periphery of the semiconductor die and the GaN layer is recessed from the outer periphery.

11. The method of claim 8, further comprising forming a plurality of dielectric layers on the GaN layer.

12. The method of claim 8, wherein defining the plurality of trenches is performed at front-end-of-line (FEOL).

13. The method of claim 8, wherein defining the plurality of trenches is performed at middle-of-line (MOL).

14. The method of claim 8, wherein defining the plurality of trenches is performed at back-end-of-line (BEOL).

15. A semiconductor die comprising:
a silicon layer defining an outer periphery of the semiconductor die; and
a gallium nitride (GaN) layer disposed on the silicon layer and recessed from the outer periphery.

16. The semiconductor die of claim 15, wherein the GaN layer comprises one or more gallium nitride layers of different compositions.

17. The semiconductor die of claim 15, further comprising a plurality of dielectric layers disposed on the GaN layer.

18. The semiconductor die of claim 15, wherein the recess in the GaN layer is formed at front-end-of-line (FEOL).

19. The semiconductor die of claim 15, wherein the recess in the GaN layer is formed at middle-of-line (MOL).

20. The semiconductor die of claim 15, wherein the recess in the GaN layer is formed at back-end-of-line (BEOL).
